(19) United States
(12) Patent Application Publication
(10) Pub. No.: US 2018/0070041 A1
(43) Pub. Date: Mar. 8, 2018

(54) SOLID-STATE IMAGE SENSOR, METHOD OF MANUFACTURING THE SAME, AND CAMERA

(71) Applicant: CANON KABUSHIKI KAISHA, Tokyo (JP)

(72) Inventors: Katsunori Hirota, Yamato-shi (JP); Toshihide Kimura, Kawasaki-shi (JP); Hideaki Ishino, Fujisawa-shi (JP)

(21) Appl. No.: 15/672,538

(22) Filed: Aug. 9, 2017

(30) Foreign Application Priority Data
Sep. 7, 2016 (JP) 2016-174963

(51) Int. Cl. H04N 5/3745; H01L 27/146; H01L 27/148; H04N 5/335; H04N 3/14

(52) U.S. Cl. CPC H04N 5/37452; H01L 27/14612; H01L 27/14831; H01L 27/1463; H01L 27/14605; H04N 5/37457; H04N 3/14; H04N 5/335

(57) ABSTRACT

A solid-state image sensor is provided. The solid-state image sensor comprises a pixel region including a photoelectric conversion unit formed in a substrate. A first silicon nitride layer is arranged to cover at least part of the photoelectric conversion unit, and a concentration of chlorine contained in the first silicon nitride layer falls within a range of 1 atomic % to 3 atomic %.

### BACKGROUND OF THE INVENTION

### Field of the Invention

The present invention relates to a solid-state image sensor, a method of manufacturing the same, and a camera.

### Description of the Related Art

There is known a technique of forming, on a photoelectric conversion unit, a silicon nitride layer functioning as an antireflection film to efficiently use light entering the photoelectric conversion unit. Japanese Patent Laid-Open No. 2013-84693 discloses a technique of forming a silicon nitride layer on a photoelectric conversion unit by a low-pressure chemical vapor deposition (LP-CVD) method using hexachlorodisilane (HCD) as a source gas. Furthermore, Japanese Patent Laid-Open No. 2001-168092 discloses that in manufacturing a semiconductor device, HCD is used to deposit silicon nitride to fill a wiring line groove.

### SUMMARY OF THE INVENTION

The present inventors have found that the characteristics of a solid-state image sensor, such as a generated dark current and sensitivity, change depending on the concentration of chlorine contained in silicon nitride at the time of deposition.

Some embodiments of the present invention provide a technique advantageous in improving the characteristics of the solid-state image sensor.

According to some embodiments, a solid-state image sensor comprising: a pixel region including a photoelectric conversion unit formed in a substrate, wherein a first silicon nitride layer is arranged to cover at least part of the photoelectric conversion unit, and a concentration of chlorine contained in the first silicon nitride layer falls within a range of 1 atomic % to 3 atomic %, is provided.

According to some other embodiments, a method of manufacturing a solid-state image sensor including a pixel region that includes a photoelectric conversion unit and a first transistor and a peripheral circuit region that includes a second transistor, the method comprising: forming the pixel region and the peripheral circuit region in a substrate; and forming a first silicon nitride layer to cover at least part of the photoelectric conversion unit, wherein a concentration of chlorine contained in the first silicon nitride layer falls within a range of 1 atomic % to 3 atomic %, is provided.

Further features of the present invention will become apparent from the following description of exemplary embodiments (with reference to the attached drawings).

### BRIEF DESCRIPTION OF THE DRAWINGS

FIGS. 1A and 1B are views for explaining an example of the arrangement of a solid-state image sensor and an example of the circuit arrangement of each of pixels arranged in the solid-state image sensor according to an embodiment of the present invention;

FIGS. 2A and 2B are a plan view and a sectional view respectively showing the example of the arrangement of the solid-state image sensor shown in FIG. 1;

FIG. 3 is a graph for explaining the relationship between the chlorine concentration of a silicon nitride layer and a dark current and optical absorption coefficient;

FIGS. 4A to 4C are sectional views showing an example of a method of manufacturing the solid-state image sensor shown in FIG. 1;

FIGS. 5A to 5C are sectional views showing the example of the method of manufacturing the solid-state image sensor shown in FIG. 1; and

FIGS. 6A to 6C are sectional views showing the example of the method of manufacturing the solid-state image sensor shown in FIG. 1.

### DESCRIPTION OF THE EMBODIMENTS

Detailed embodiments and examples of an image sensor according to the present invention will be described below with reference to the accompanying drawings. Note that in the following description and drawings, common reference numerals denote common components throughout a plurality of drawings. Hence, the common components will be described by cross-referring to the plurality of drawings, and a description of components denoted by common reference numerals will appropriately be omitted.

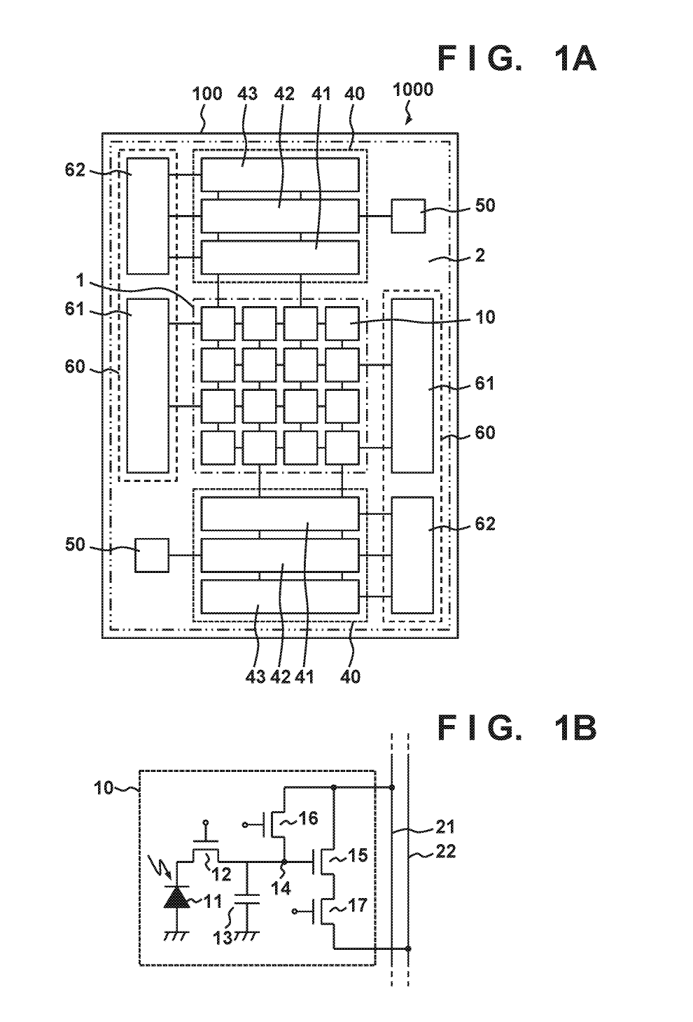

The arrangement of a solid-state image sensor and a method of manufacturing the solid-state image sensor according to an embodiment of the present invention will be described with reference to FIGS. 1A to 6C. FIG. 1A is a view showing an example of the arrangement of a solid-state image sensor 1000 according to the embodiment of the present invention. The solid-state image sensor 1000 includes a pixel region 1 in which a plurality of pixels 10 is arranged, and a peripheral circuit region 2 in which peripheral circuits for, for example, processing signals output from the pixels 10 are arranged. The pixel region 1 and the peripheral circuit region 2 are formed on one substrate 100. The substrate 100 may be a semiconductor substrate such as a silicon substrate. Referring to FIG. 1A, a region surrounded by a one-dot dashed line is the pixel region 1, and a region between the one-dot dashed line and a two-dot dashed line is the peripheral circuit region 2. The peripheral circuit region 2 may be located around the pixel region 1 and between the pixel region 1 and the edges of the substrate 100. The pixel region 1 shown in FIG. 1A shows an example of an area sensor in which the plurality of pixels 10 is arranged in a two-dimensional array. However, the pixel region 1 may be a linear sensor in which the plurality of pixels 10 is arranged one-dimensionally.

FIG. 1B is a view showing an example of the circuit arrangement of each of the pixels 10 arranged in the pixel region 1. The pixel 10 includes a photoelectric conversion unit 11, a transfer element 12, a capacitive element 13, an amplification element 15, a reset element 16, and a selection element 17. The photoelectric conversion unit 11 converts incident light into an electrical signal. In this embodiment, a photodiode formed in the substrate 100 is used as the photoelectric conversion unit 11.

Transistors formed in the substrate 100 are respectively used as the amplification element 15, the reset element 16, and the selection element 17. In this specification, each transistor arranged in the pixel 10 will be referred to as a pixel transistor hereinafter.

A MISFET (Metal-Insulator-Semiconductor Field-Effect Transistor) can be used as a pixel transistor. For example, among MISFETs, a MOSFET (Metal-Oxide-Semiconductor Field-Effect Transistor) obtained by using a silicon oxide film as the gate insulating film of the MISFET may be used. However, the gate insulating film is not limited to this. For example, a silicon nitride film may be used. Furthermore, for example, the gate insulating film may be a so-called high-dielectric constant gate insulating film such as a hafnium oxide film. The gate insulating film may be obtained by stacking the above films, or may be made of a compound such as silicon oxynitride.

The transfer element 12 has a MOS gate structure. Thus, if the transfer element 12 serves as a gate, the photoelectric conversion unit 11 serves as a source, and the capacitive element 13 serves as a drain, they can be considered as a transistor. The photoelectric conversion unit 11, the transfer element 12, and the capacitive element 13 can be referred to as a pixel transistor.

The transfer element 12 transfers, to the capacitive element 13, signal charges generated in the photoelectric conversion unit 11. The capacitive element 13 functions as a charge-voltage conversion element for generating, in a node 14, a voltage corresponding to the amount of signal charges and the capacitance of the capacitive element 13. The gate of the amplification element 15 is connected to the capacitive element 13 via the node 14. The drain of the amplification element 15 is connected to a power supply line 21, and the source of the amplification element 15 is connected to an output line 22 via the selection element 17. The capacitive element 13 and the gate of the amplification element 15 are connected to the power supply line 21 via the reset element 16. By performing the ON operation of the reset element 16, the potential of the node 14 is reset to that corresponding to the potential of the power supply line 21. By performing the ON operation of the selection element 17, a signal corresponding to the potential of the node 14 is output from the amplification element 15 to the output line 22. The arrangement of the pixel 10 is not limited to that shown in FIG. 1B as long as an electrical signal generated by photoelectric conversion unit 11 in accordance with incident light can be output to the peripheral circuit region 2.

In this embodiment, a MOSFET (nMOSFET) with an n-type channel (inversion layer) is used as each pixel transistor but a pMOSFET with a p-type channel may be included. The pixel transistors may include a transistor other than the MISFET. For example, the amplification element 15 may be a JFET (Junction FET) or a bipolar transistor.

In the following description of this specification, a conductivity type matching a conductivity type in which charges handled as signal charges in the pixel region 1 are used as majority carriers will be referred to as the first conductivity type hereinafter, and a conductivity type matching a conductivity type in which charges handled as signal charges are used as minority carriers will be referred to as the second conductivity type hereinafter. For example, if electrons are used as signal charges, an n type is set as the first conductivity type and a p type is set as the second conductivity type.

Referring back to FIG. 1A, the peripheral circuit region 2 will be described. In the peripheral circuit region 2, a signal processing unit 40 for processing an electrical signal generated in each of the pixels 10 is arranged. Furthermore, the peripheral circuit region 2 includes an output unit 50 for outputting the signal processed by the signal processing unit 40 to the outside of the solid-state image sensor 1000, and a control unit 60 for controlling the signal processing unit 40 and the pixel region 1 in which the plurality of pixels 10 is arranged. The signal processing unit 40, the output unit 50, and the control unit 60 can be referred to as peripheral circuits.

In this embodiment, the signal processing unit 40 includes an amplification circuit 41 with a plurality of column amplifiers, a conversion circuit 42 with a plurality of AD converters, and a horizontal scanning circuit 43 for selecting an output from the conversion circuit 42 and outputting it to the output unit 50. The signal processing unit 40 can perform correlation double sampling (CDS) processing, parallel-serial conversion processing, analog-digital conversion processing, and the like. The output unit 50 includes an electrode pad and a protection circuit. The control unit 60 includes a vertical scanning circuit 61 and a timing generation circuit 62. The arrangement of the peripheral circuit region 2 is not limited to this as long as it is possible to appropriately process an electrical signal generated in each pixel 10 in the pixel region 1, and output the processed signal to the outside of the solid-state image sensor 1000.

The peripheral circuits can be formed by a plurality of transistors, for example, using MISFETs and the like, similarly to the pixel transistors, and may be formed by CMOS (Complementary MOS) circuits each including an nMOSFET and a pMOSFET. In this specification, a transistor forming each peripheral circuit will be referred to as a peripheral transistor hereinafter. When a conductivity type is specified, each transistor will be referred to as a peripheral nMOSFET or a peripheral pMOSFET hereinafter. Furthermore, the peripheral circuits can include not only active elements such as a transistor and a diode but also passive elements such as a resistance element and a capacitive element.

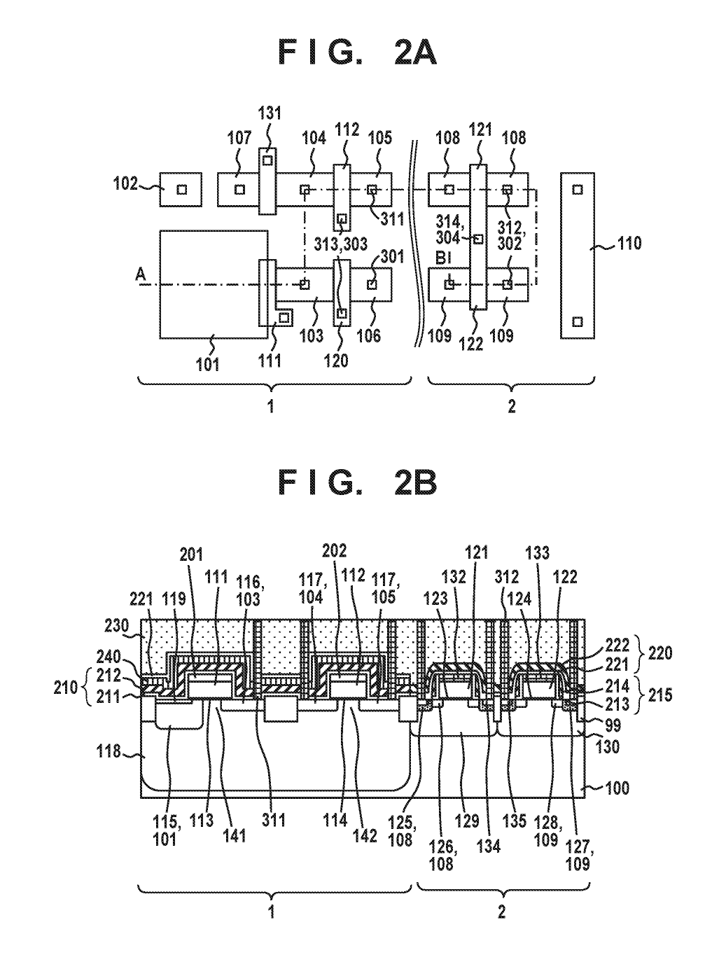

The solid-state image sensor 1000 according to this embodiment will be described in detail with reference to FIGS. 2A and 2B. FIGS. 2A and 2B are a plan view and a sectional view each showing part of the pixel region 1 and part of the peripheral circuit region 2.

Referring to FIG. 2A, regions 101, 103, and 106 respectively correspond to the photoelectric conversion unit 11, the capacitive element 13 and the node 14 for detecting charges, and the drain region of the reset element 16. Regions 104, 105, and 107 respectively correspond to the source region of the amplification element 15, the drain region of the amplification element 15, and the source of the selection element 17. In addition, the region 103 also serves as the source of the reset element 16, and the region 104 also serves as the drain region of the selection element 17. Gate electrodes 111, 120, 112, and 131 respectively correspond to the gate of the transfer element 12, the gate of the reset element 16, the gate of the amplification element 15, and the gate of the selection element 17. Regions 108 and 109 correspond to the source/drain regions of a peripheral nMOSFET and those of a peripheral pMOSFET, respectively. Gate electrodes 121 and 122 respectively correspond to the gates of the peripheral nMOSFET and peripheral pMOSFET. Each gate electrode is made of polysilicon (polycrystalline silicon). The gate electrodes 121 and 122 are integrally formed in this embodiment but may be individually formed. The regions 103 to 109 corresponding to the gate electrodes and source/drain regions are connected to wiring lines (not shown) via electrically conductive members 311, 312, 313, and 314 embedded in contact holes 301, 302, 303, and 304.

Referring to FIG. 2A, in the pixel region 1, a reference contact region 102 of the pixel 10 can be arranged. The reference contact region 102 supplies a reference potential such as a ground potential to the pixel 10 via a wiring line (not shown). By arranging the plurality of reference contact regions 102 in the pixel region 1, it is possible to suppress a variation in reference potential in the pixel region 1, and suppress the occurrence of shading in a captured image.

Referring to FIG. 2A, a resistance element 110 can be arranged in the peripheral circuit region 2. The resistance element 110 is an impurity region formed in the substrate 100. By providing contacts at two ends of the impurity region, a resistance corresponding to an impurity concentration, the distance between the contacts, and the width of the impurity region can be obtained. In this embodiment, the impurity region of the resistance element 110 is an impurity region of an n type as the first conductivity type, which is formed in a well of a p type as the second conductivity type, but may be a p-type impurity region formed in an n-type well. Alternatively, a resistance element formed by an n-type impurity region and a resistance element formed by a p-type impurity region may coexist. In the peripheral circuit region 2, for example, passive elements, except for the resistance element 110, such as a resistance element and a capacitive element each of which has a MOS structure made of polysilicon may be arranged.

In this embodiment, the regions 101 and 103, the regions 104, 105, 106, and 107 corresponding to the source/drain regions of the pixel transistors, the reference contact regions 102, and the regions 108 corresponding to the source/drain regions of the peripheral nMOSFET are n-type impurity regions. The regions 109 corresponding to the source/drain regions of the peripheral pMOSFET are p-type impurity regions.

FIG. 2B is a sectional view taken along a line A-B in FIG. 2A. The substrate 100 is a semiconductor substrate such as a silicon substrate, as described above. The substrate 100 is divided into a plurality of active regions by element isolation regions 99. Each element isolation region 99 can be implemented by an insulator for element isolation formed by an STI (Shallow Trench Isolation) method, a LOCOS (Local Oxidation of Silicon) method, or the like. In each active region, impurity regions are formed, and each impurity region forms a semiconductor element. Therefore, an impurity region (for example, a p-type impurity region) for p-n junction isolation may be provided as an element isolation region.

In each active region of the substrate 100, a well of a conductivity type corresponding to the conductivity type of each element is arranged. A p-type well 118 is arranged in the pixel region 1, and a p-type well 129 and an n-type well 130 are arranged in the peripheral circuit region 2. In the reference contact region 102 shown in FIG. 2A, a p-type impurity region having an impurity concentration higher than that of the p-type well 118 is arranged. A reference potential is supplied from the wiring line connected to the reference contact region 102 to the well 118 via the reference contact region 102.

The sectional structures of the pixel region 1 and peripheral circuit region 2 will be described with reference to FIG. 2B. For the sake of descriptive convenience, FIG. 2B and FIGS. 4A to 6C (to be described later) show the pixel region 1 and the peripheral circuit region 2 adjacent to each other. The sectional structure of the pixel region 1 will be explained first. In the region 101, an n-type accumulation region 115 forming the photoelectric conversion unit 11 is arranged. The accumulation region 115 forms a p-n junction with the p-type well 118, and functions as the photodiode of the photoelectric conversion unit 11. A p-type surface region 119 for using a buried photodiode as the photoelectric conversion unit 11 is arranged between the accumulation region 115 and the surface of the substrate 100. An impurity region 116 forming the capacitive element 13 is arranged in the region 103. The impurity region 116 serves as a floating diffusion region. In each of the source/drain regions of the amplification element 15, reset element 16, and selection element 17, an n-type impurity region 117 is arranged. FIG. 2B shows the cross section of the amplification element 15 but the reset element 16 and the selection element 17 can have the same arrangement.

Each of gate insulating films 113 and 114 and the gate insulating films of elements such as the remaining pixel transistors of the pixel 10 is mainly made of silicon oxide but can be made of silicon oxide containing a slight amount (for example, less than 10%) of nitrogen by plasma nitridation or thermal oxinitridation. Silicon oxide containing nitrogen has a dielectric constant higher than that of pure silicon oxide, and thus the driving capability of the transistor can be improved. However, the arrangement of the gate insulating film is not limited to this, and may be made of pure silicon oxide or silicon nitride. Alternatively, a high-dielectric constant material such as hafnium oxide may be used, as described above, or a compound of these materials or a stacked film may be used. The upper surfaces of the gate electrodes 111 and 112 arranged on the gate insulating film 113 and 114 on the substrate 100 are covered with insulating layers 201 and 202 containing silicon oxide or silicon nitride.

An insulating film 210 including a silicon oxide layer 211 and a silicon nitride layer 212 (first silicon nitride layer) is arranged on the pixel region 1. The insulating film 210 covers the upper and side surfaces of the gate electrodes 111 and 112 via the insulating layers 201 and 202. Although not shown in FIG. 2B, similarly, the insulating film 210 covers the upper and side surfaces of the gate electrodes 120 and 131 via the insulating layers. The insulating film 210 also covers the region 101 forming the photoelectric conversion unit 11 and the regions 103 to 107 corresponding to the source/drain regions of the pixel transistors. In this case, the distance between the surface of the substrate 100 and the lower surface of a portion of the silicon nitride layer 212, which covers the region 101 forming the photoelectric conversion unit 11, is shorter than that between the surface of the substrate 100 and the upper surface of the gate electrode of each pixel transistor.

The insulating film 210 is a stacked film of the silicon oxide layer 211 and the silicon nitride layer 212, and the silicon oxide layer 211 and the silicon nitride layer 212 have an interface. In this embodiment, the silicon oxide layer 211 contacts the side surfaces of the gate electrodes 111, 112, 120, and 131. However, another layer may be sandwiched between the silicon oxide layer 211 and the side surfaces of the gate electrodes 111, 112, 120, and 131. The silicon oxide layer 211 contacts the region 101 forming the photoelectric conversion unit 11 and the regions 103 to 107 corresponding to the source/drain regions of the pixel transistors, and forms an interface with the substrate 100. However, another layer may exist between the silicon oxide layer 211 and those regions.

The insulating film 210 as a stacked film of the silicon oxide layer 211 having a refractive index of about 1.6 and the silicon nitride layer 212 having a refractive index of about 2.0 covers the region 101 forming the photoelectric conversion unit 11. This makes it possible to use the insulating film 210 as an antireflection film of light entering the photoelectric conversion unit 11. To obtain a satisfactory antireflection characteristic, the thickness of the silicon nitride layer 212 may be equal to or larger than that of the silicon oxide layer 211.

A protective film 240 is arranged on the insulating film 210 to cover it. The protective film 240 can be a single-layer film of an insulator such as silicon oxide or silicon nitride or a stacked film of such insulators. A silicon oxide layer 221 is arranged on the protective film 240 to cover it. An insulating film 230 is arranged on the silicon oxide layer 221 to cover it. The insulating film 230 can be made of silicon oxide or silicate glass such as BPSG, BSG, or PSG. The upper surface of the insulating film 230 can be a flat surface which does not substantially reflect the unevenness of the surface of the underlayer.

The contact holes 301 and 303 are formed to extend through each of the insulating film 230, the silicon oxide layer 221, the protective film 240, and the insulating film 210. The electrically conductive members 311 and 313 for electrically connecting the wiring lines (not shown) and the pixel transistors are arranged in the contact holes 301 and 303, respectively. In the arrangement shown in FIG. 2A, the electrically conductive members 311 are connected to the reference contact region 102 and the regions 103 to 107 corresponding to the source/drain regions of the pixel transistors, and the electrically conductive members 313 are connected to the gate electrodes 111, 112, 120, and 131. Each of the electrically conductive members 311 and 313 is a contact plug mainly made of a metal such as tungsten.

The concentration of chlorine contained in the silicon nitride layer 212 of the insulating film 210 will now be described. The present inventors have found by experiment that the characteristics of the solid-state image sensor change depending on the concentration of chlorine contained in the silicon nitride layer 212. More specifically, when the silicon nitride layer 212 containing chlorine covers the region 101, the dangling bond of the photoelectric conversion unit 11 is terminated by hydrogen or chlorine contained in the silicon nitride layer 212, thereby making it possible to reduce the dark current of the solid-state image sensor 1000. Meanwhile, if the silicon nitride layer 212 contains a large amount of chlorine, the optical absorption coefficient (k value) on the short wavelength side of light increases. Therefore, if the silicon nitride layer 212 containing a large amount of chlorine covers the region 101, the silicon nitride layer 212 absorbs incident light to decrease the light amount of light entering the photoelectric conversion unit 11, and thus the sensitivity significantly degrades. Consequently, the silicon nitride layer 212 needs to contain at least chlorine and an upper limit value needs to be set for the chlorine concentration.

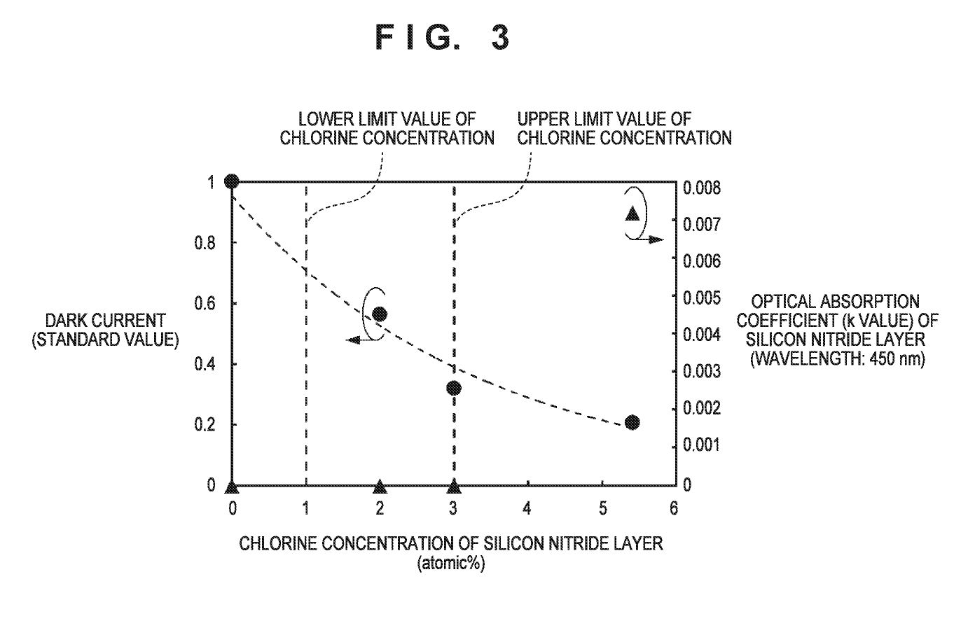

FIG. 3 is a graph for explaining the relationship between the chlorine concentration of the silicon nitride layer 212 and the dark current and k value. A plot of circles indicates the dark current, and a plot of triangles indicates the k value. It is apparent from FIG. 3 that as the chlorine concentration of the silicon nitride layer 212 increases, the dark current of the photoelectric conversion unit 11 decreases. To lower the level of the dark current by 20% or more, as compared with a case in which a silicon nitride layer containing no chlorine is used, the concentration of chlorine contained in the silicon nitride layer 212 is set to 1 atomic %. By setting the chlorine concentration to 2 atomic %, the level of the dark current can be lowered by about 40 to 50%, as compared with a case in which a silicon nitride layer containing no chlorine is used. If the chlorine concentration of the silicon nitride layer 212 is set to 2 atomic %, a variation in concentration of chlorine contained in the silicon nitride layer 212 falls within the range of ±0.3 atomic %. By setting the chlorine concentration to 3 atomic %, it is possible to lower the level of the dark current by 60 to 70%, as compared with a case in which a silicon nitride layer containing no chlorine is used. In this case, a variation in concentration of chlorine falls within the range of ±0.3 atomic %. Meanwhile, it is apparent from FIG. 3 that if the chlorine concentration is set higher than 3 atomic %, the k value of incident light with a wavelength of 450 nm increases. To reduce the dark current and improve the sensitivity, the concentration of chlorine contained in the silicon nitride layer 212 is set to fall within the range of 1 atomic % to 3 atomic %. To obtain the effect of the reduction of the dark current, as described above, the chlorine concentration of the silicon nitride layer 212 may be set to, for example, 2 atomic % or higher. In consideration of a margin to suppress a decrease in sensitivity, the chlorine concentration of the silicon nitride layer 212 may be set to, for example, 2.5 atomic % or lower.

The sectional structure of the peripheral circuit region 2 will be described next. An n-type impurity region 125, an n-type impurity region 126, and a silicide layer 134 are arranged in the regions 108 corresponding to the source/drain regions of the peripheral nMOSFET. The impurity region 125 has an impurity concentration higher than that of the impurity region 126. The silicide layer 134 covers the impurity region 125. A p-type impurity region 127, a p-type impurity region 128, and a silicide layer 135 are arranged in the regions 109 corresponding to the source/drain regions of the peripheral pMOSFET. The impurity region 127 has an impurity concentration higher than that of the impurity region 128. The silicide layer 135 covers the impurity region 127. As described above, each peripheral transistor can have an LDD (Lightly Doped Drain) structure by the high-concentration impurity region 125 or 127 and the low-concentration impurity region 126 or 128.

The gate electrodes 121 and 122 are arranged on gate insulating films 123 and 124 on the substrate 100. In this embodiment, similarly to each pixel transistor of the pixel 10, the gate insulating film is a silicon oxide film mainly made of silicon oxide and containing a slight amount (for example, less than 10%) of nitrogen by plasma nitridation or thermal oxinitridation. The thicknesses of the gate insulating films 123 and 124 of the peripheral transistors may be equal to or smaller than those of the gate insulating films 113 and 114 of the pixel transistors. For example, the thicknesses of the gate insulating films 113 and 114 may fall within the range of 5.0 nm to 10 nm, and the thicknesses of the gate insulating films 123 and 124 may fall within the range of 1.0 nm to 5.0 nm. By setting different thicknesses of the gate insulating films between the pixel transistor and the peripheral transistor, it is possible to improve the pressure resistance of the pixel transistor and increase the driving speed of the peripheral transistor. Silicide layers 132 and 133 respectively forming parts of the gate electrodes 121 and 122 are arranged on the upper surfaces of the gate electrodes 121 and 122. Each peripheral transistor can have a Salicide (Self ALIgned siliCIDE) structure in which the silicide layers 132 and 134 or 133 and 135 are formed. As a metal component forming each silicide layer, titanium, nickel, cobalt, tungsten, molybdenum, tantalum, chrome, palladium, platinum, or the like may be used.

The side surfaces of the gate electrodes 121 and 122 of the peripheral transistors can be covered with side walls 215. The side walls 215 also cover the low-concentration impurity regions 126 and 128 of the regions 108 and 109. In this embodiment, each side wall 215 has a stacked structure including a silicon oxide layer 213 and a silicon nitride layer 214. The silicon oxide layer 213 is located between the silicon nitride layer 214 and the gate electrode 121 or 122 and between the silicon nitride layer 214 and the region 108 or 109. The silicon oxide layer 213 and the silicon nitride layer 214 have an interface.

An insulating film 220 including the silicon oxide layer 221 and a silicon nitride layer 222 (second silicon nitride layer) is arranged on the peripheral circuit region 2. In this embodiment, the insulating film 220 is a stacked film of the silicon oxide layer 221 and the silicon nitride layer 222, and the silicon oxide layer 211 and the silicon nitride layer 212 have an interface. However, the insulating film 220 may be a single-layer film of the silicon nitride layer 222. The silicon oxide layer 221 is located between the silicon nitride layer 214 and the silicon nitride layer 222. The silicon nitride layer 214 and the silicon oxide layer 221 have an interface. That is, each side wall 215 and the insulating film 220 have an interface. The insulating film 220 covers the silicide layers 134 and 135 of the regions 108 and 109, and has interfaces with the silicide layers 134 and 135 of the regions 108 and 109. In this embodiment, the silicide layers 134 and 135 are arranged. However, the silicide layers 134 and 135 need not be arranged. In this case, the insulating film 220 covers the high-concentration impurity regions 125 and 127, and has interfaces with the high-concentration impurity regions 125 and 127. Similarly to the pixel region 1, the insulating film 230 is arranged on the insulating film 220. The contact holes 302 and 304 are formed to extend through each of the insulating film 230 and the insulating film 220 including the silicon oxide layer 221 and the silicon nitride layer 222. The electrically conductive members 312 and 314 for electrically connecting the regions 108 as the source/drain regions of the peripheral transistor and the gate electrodes 121 and 122 to the wiring lines (not shown) are arranged in the contact holes 302 and 304. Similarly to the electrically conductive members 311 and 313, each of the electrically conductive members 312 and 314 is a contact plug mainly made of a metal such as tungsten.

A wiring pattern (not shown) including the wiring lines connected to the electrically conductive members 311, 312, 313, and 314 is arranged on the insulating film 230. A plurality of wiring patterns can be stacked via interlayer insulating films. The wiring pattern can be made of a metal such as aluminum or copper. A color filter (not shown), a microlens (not shown), and the like can be arranged on the light-receiving surface side of the substrate 100 which light enters. These arrangements can be formed using an existing technique and a description thereof will be omitted. The solid-state image sensor 1000 is accommodated in, for example, a package, and it is possible to create an image capturing system such as a camera or information terminal incorporating the package.

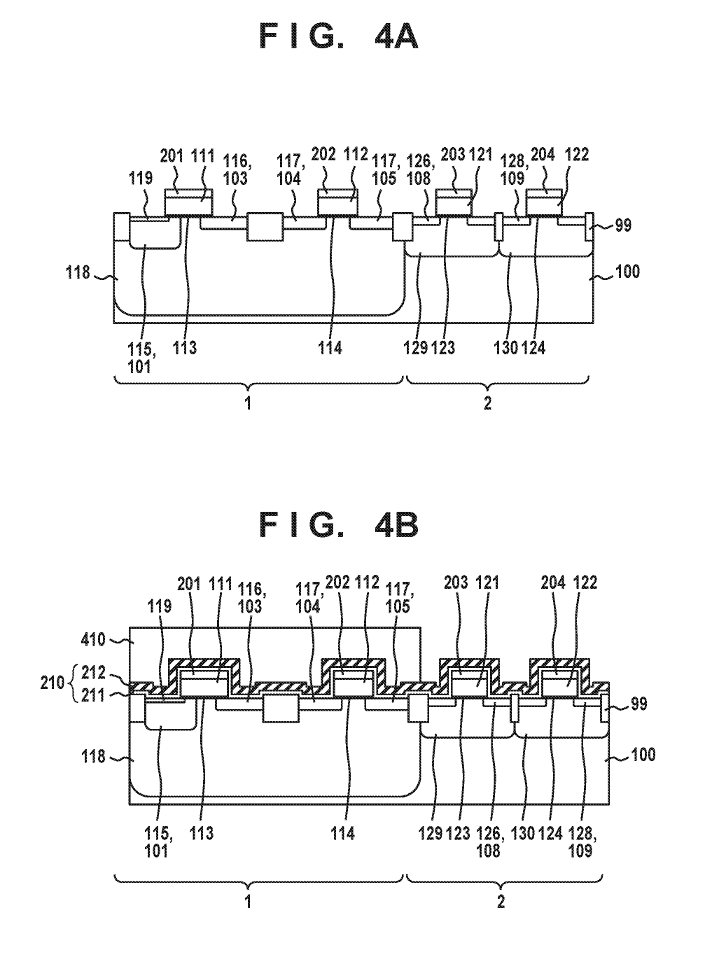

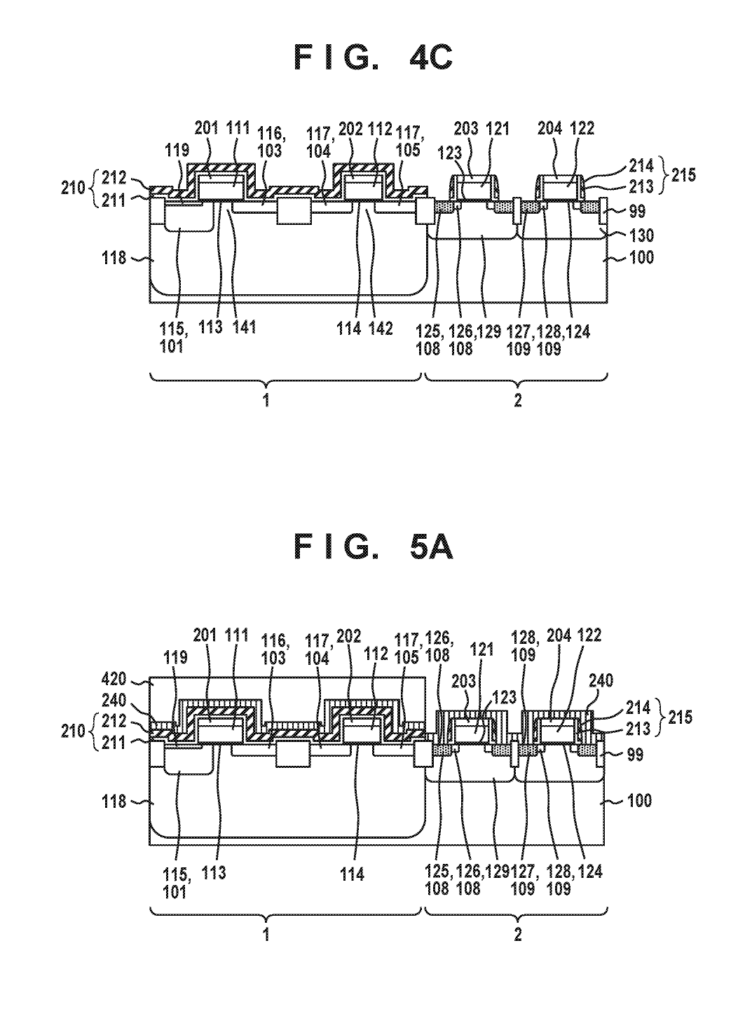

A method of manufacturing the solid-state image sensor 1000 will be described next with reference to FIGS. 4A to 6C. FIGS. 4A to 6C are sectional views respectively showing the manufacturing processes of the solid-state image sensor 1000. As shown in FIG. 4A, the pixel transistors and the peripheral transistors are formed. In a step of forming the pixel transistors and peripheral transistors, the element isolation regions 99 are formed in the substrate 100 using the STI method, the LOCOS method, or the like. As the substrate 100, a silicon wafer cut out from a silicon ingot or a wafer obtained by epitaxially growing a single crystal silicon layer on a silicon wafer may be used. After the formation of the element isolation regions 99, the wells 118 and 129 of the second conductivity type (p type) and the well 130 of the first conductivity type (n type) are formed.

After the formation of the wells 118, 129, and 130, the gate insulating films 113, 114, 123, and 124 are formed, and polysilicon is deposited on the gate insulating films 113, 114, 123, and 124. The gate insulating films 113, 114, 123, and 124 may be simultaneously formed in the pixel region 1 and the peripheral circuit region 2. As described above, to form films of different thicknesses in the pixel region 1 and the peripheral circuit region 2, the gate insulating films 113, 114, 123, and 124 may be formed using different steps. Subsequently, in accordance with the conductivity type of the corresponding transistor, an impurity is implanted into each portion serving as a polysilicon gate electrode using an ion implantation method or the like. After the implantation of the impurity, the insulating layers 201 and 202 and insulating layers 203 and 204 serving as hard masks are formed on portions respectively serving as the polysilicon gate electrodes 111, 112, 121, and 122. After that, polysilicon in openings is etched using the insulating layers 201, 202, 203, and 204 as masks. In this step, the n-type gate electrodes 111, 112, and 121 and the p-type gate electrode 122 are formed.

Next, the n-type accumulation region 115 and the p-type surface region 119 are formed. In addition, the impurity region 116 of the region 103, and the n-type impurity regions 117 with the single drain structure, which serve as the source/drain regions of the pixel transistor, are formed. Furthermore, the low-concentration n-type impurity region 126 and p-type impurity region 128 of the LDD structures of the peripheral transistors are formed. A dose when forming the impurity regions 116 and 117 of the pixel 10 may fall within the range of 5×10¹² to 5×10¹⁴ (ions/cm²), and further fall within the range of 1×10¹³ to 1×10¹⁴ (ions/cm²). A dose when forming the low-concentration impurity regions 126 and 128 of the LDD structures may fall within the range of 5×10¹² to 5×10¹⁴ (ions/cm²), and further fall within the range of 1×10¹³ to 1×10¹⁴ (ions/cm²). Therefore, implantation of an impurity into the impurity regions 116 and 117 and implantation of an impurity into the impurity region 126 may be performed simultaneously. An impurity may be implanted into the accumulation region 115, the impurity regions 116, 117, 126, and 128, and the surface region 119 in any order.

As shown in FIG. 4B, the insulating film 210 including the silicon oxide layer 211 and the silicon nitride layer 212 is formed. The insulating film 210 covers the upper and side surfaces of the gate electrodes 111, 112, 121, and 122, the regions 103, 104, 105, 108, and 109 which serve as the source/drain regions of the pixel transistors and peripheral transistors, and the region 101. In the step shown in FIG. 4A, the impurity regions 116, 117, 126, and 128 are formed in the source/drain regions, and the insulating film 210 covers the impurity regions 116, 117, 126, and 128.

The insulating film 210 is a stacked film of the silicon oxide layer 211 and the silicon nitride layer 212, and is formed so that the silicon oxide layer 211 and the silicon nitride layer 212 contact each other. The step of forming the insulating film 210 includes a step of forming the silicon oxide layer 211 and a step of forming the silicon nitride layer 212. As described above, the insulating film 210 may cover at least the region 101 serving as the photoelectric conversion unit 11 to be used as an antireflection film, and the thickness of the silicon nitride layer 212 may be equal to or larger than that of the silicon oxide layer 211 to obtain a satisfactory antireflection characteristic. For example, the thickness of the silicon oxide layer 211 may fall within the range of 5 nm to 20 nm, and the thickness of the silicon nitride layer 212 may fall within the range of 20 nm to 100 nm.

In this embodiment, the silicon oxide layer 211 and the silicon nitride layer 212 are formed using a CVD (Chemical Vapor Deposition) method. The silicon oxide layer 211 is formed using a low-pressure CVD (LPCVD) method as a thermal CVD method in which the pressure (generated pressure) of a process gas containing a source gas such as TEOS falls within the range of 20 Pa to 200 Pa. In this case, the deposition temperature (substrate temperature) may fall within the range of 500° C. to 800° C. The process gas indicates the whole gas in a deposition chamber, which contains at least a source gas and contains a carrier gas added as needed. As the carrier gas, nitrogen or a rare gas such as helium or argon can be used. The generated pressure indicates the pressure (total pressure) of the process gas in the deposition chamber.

The silicon nitride layer 212 is formed by the LPCVD method using the process gas containing, as source gases, ammonia (NH₃) and hexachlorodisilane (HCD). In this case, the pressure (generated pressure) of the process gas may fall within the range of 20 Pa to 200 Pa, and the deposition temperature (substrate temperature) may fall within the range of 500° C. to 800° C.

As described above, to reduce the dark current and improve the sensitivity, the chlorine concentration of the silicon nitride layer 212 used as an antireflection film is set to fall within the range of 1 atomic % to 3 atomic %. If the chlorine concentration of the silicon nitride layer 212 is set to 1 atomic %, for example, the following deposition conditions can be adopted as the deposition conditions of the silicon nitride layer 212.

Deposition temperature: 500 to 700° C.
HCD: 10 to 20 sccm
NH₃: 800 to 1,600 sccm
Generated pressure: 10 to 200 Pa
If the chlorine concentration of the silicon nitride layer 212 is set to 2 atomic %, for example, the following deposition conditions can be adopted as the deposition conditions of the silicon nitride layer 212.
Deposition temperature: 500 to 700° C.
HCD: 20 to 40 sccm
NH₃: 800 to 1,600 sccm
Generated pressure: 10 to 200 Pa
If the chlorine concentration of the silicon nitride layer 212 is set to 3 atomic %, for example, the following deposition conditions can be adopted as the deposition conditions of the silicon nitride layer 212.
Deposition temperature: 500 to 700° C.
HCD: 40 to 60 sccm
NH₃: 800 to 1,600 sccm
Generated pressure: 10 to 200 Pa
As described above, the chlorine concentration of the silicon nitride layer 212 can be controlled within the range of ±0.3 atomic % with respect to the target chlorine concentration. Furthermore, by increasing/decreasing the flow rate of HCD in the process gas, it is possible to readily change the chlorine concentration of the silicon nitride layer 212.

The silicon nitride layer 212 formed using the process gas containing HCD and NH₃ as source gases contains a large amount of hydrogen in addition to silicon, nitrogen, and chlorine, as disclosed in Japanese Patent Laid-Open No. 2013-84693. Thus, the silicon nitride layer 212 can serve as a hydrogen supply source for terminating the dangling bond of each pixel transistor. When forming at least the silicon nitride layer 212, the composition ratio of chlorine in the silicon nitride layer 212 can be lower than each of the composition ratios of silicon, nitrogen, and hydrogen.

After the formation of the insulating film 210, the side walls 215 are formed on the side surfaces of the gate electrodes 121 and 122 of the peripheral transistors. As shown in FIG. 4B, a mask pattern 410 is formed on the insulating film 210 using, for example, a photoresist. The mask pattern 410 is formed to cover at least part of the region 101 serving as the photoelectric conversion unit 11 of the pixel region 1. When the mask pattern 410 covers at least part of the region 101, the silicon nitride layer 212 containing chlorine for reducing the dark current remains on at least part of the region 101. In this embodiment, the mask pattern 410 covers the pixel region 1 including the regions 101, 103, 104, and 105, and has an opening in the peripheral circuit region 2. Next, the insulating film 210 in the opening of the mask pattern 410 is etched (etched back). By removing the mask pattern 410 after etching, the side walls 215 are formed to cover the side surfaces of the gate electrodes 121 and 122 of the peripheral transistors, as shown in FIG. 4C. Each side wall 215 can be a stacked layer of the silicon oxide layer 213 and the silicon nitride layer 214 (third silicon nitride layer). The silicon oxide layer 213 is part of the silicon oxide layer 211 of the insulating film 210, and the silicon nitride layer 214 is part of the silicon nitride layer 212 of the insulating film 210. Therefore, the concentration of chlorine contained in the silicon nitride layer 212 of the insulating film 210 is equal to that of chlorine contained in the silicon nitride layer 214 of the side wall 215, and can fall within the range of 1 atomic % to 3 atomic %.

In etching for forming the side walls 215, regions where the impurity regions 125 and 127 of the regions 108 are formed are exposed. In this etching step, the region where the resistance element 110 shown in FIG. 2A is formed is exposed.

During etching for forming the side walls 215, the mask pattern 410 covers the region 101, and the portion on the region 101 of the insulating film 210 remains. This can suppress damage to the photoelectric conversion unit 11 at the time of etching, thereby reducing noise generated in the photoelectric conversion unit 11. When the mask pattern 410 covers the gate electrodes 111 and 112 and the regions 103 and 104, the insulating film 210 arranged on channel regions 141 and 142 and the source/drain regions of the pixel transistors remains. This can suppress damage to the pixel transistors at the time of etching, thereby reducing noise generated in each pixel transistor.

In etching for forming the side walls 215, after exposing the regions where the impurity regions 125 and 127 of the regions 108 are formed, the high-concentration impurity regions 125 and 127 which are self-aligned along the side surfaces of the side walls 215 are formed. A mask pattern is formed to cover the pixel region 1 and the peripheral pMOSFET, and an n-type impurity is implanted by an ion implantation method or the like using the mask pattern, the gate electrode 121, and the side walls 215 as masks. This forms the impurity region 125 of the peripheral nMOSFET. Furthermore, a mask pattern is formed to cover the pixel region 1 and the peripheral nMOSFET, and a p-type impurity is implanted by an ion implantation method or the like using the mask pattern, the gate electrode 122, and the side walls 215 as masks. This forms the impurity region 127 of the peripheral pMOSFET. The impurity regions 125 and 127 are formed in any order. The dose when forming the high-concentration impurity regions 125 and 127 forming the LDD structures may fall within the range of 5×10¹⁴ to 5×10¹⁶ (ions/cm²), and further fall within the range of 1×10¹⁵ to 1×10¹⁶ (ions/cm²). The dose when forming the impurity regions 125 and 127 is higher than that when forming the impurity regions 126 and 128 described above. As a result, the impurity concentrations of the impurity regions 125 and 127 are higher than those of the impurity regions 126 and 128.

When forming at least one of the impurity regions 125 and 127, an impurity may be simultaneously implanted into a region where the resistance element 110 is to be formed. This forms the resistance element 110 as a diffused resistor. The impurity concentration is low for the dose when forming the impurity regions 126 and 128, and it may be impossible to decrease the resistance value of the resistance element 110 to fall within a practical range. On the other hand, with the dose when forming the impurity regions 125 and 127, the impurity region of the resistance element 110 having a practical resistance value can be formed. In etching for forming the side walls 215, the region where the resistance element 110 is to be formed is exposed, and the impurity region of the resistance element 110 is formed simultaneously with implantation of an impurity into the impurity region 125 or 127.

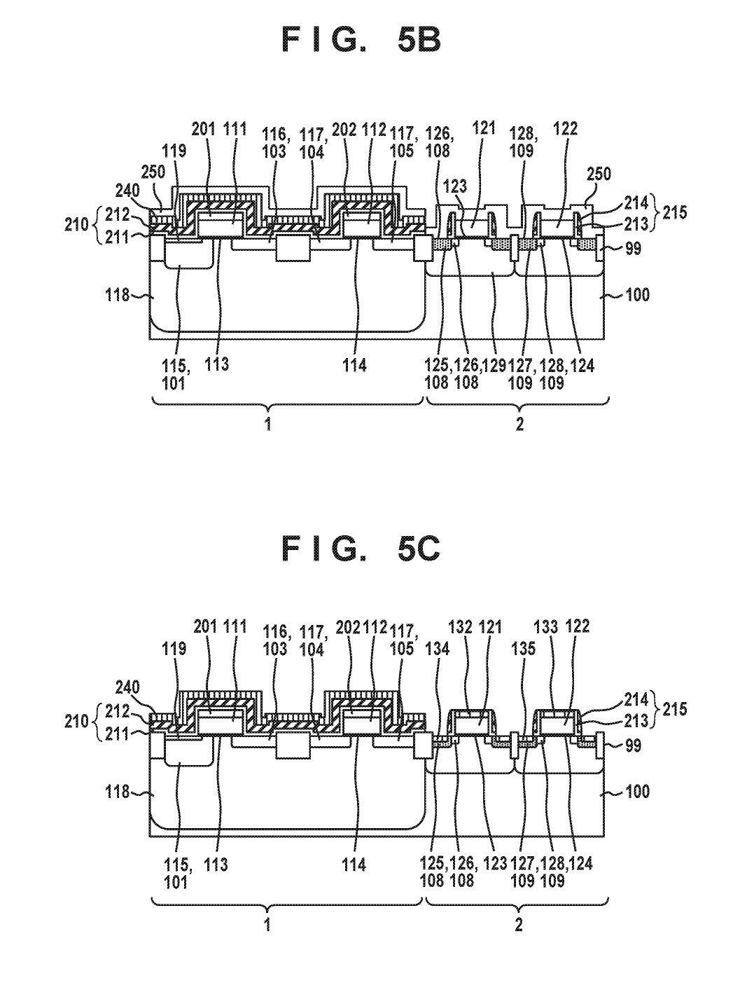

After the formation of the LDD structures of the peripheral transistors, the protective film 240 is formed to cover the pixel region 1 and the peripheral circuit region 2, as shown in FIG. 5A. The protective film 240 is made of, for example, silicon oxide, and has a thickness falling within the range of 30 nm to 130 nm. After the formation of the protective film 240, a mask pattern 420 is formed to cover the pixel region 1 using a photoresist or the like. After the formation of the mask pattern 420, the protective film 240 in the opening portion of the mask pattern 420 is etched. By etching, portions located on the regions 108 and 109 of the protective film 240 and portions located on the gate electrodes 121 and 122 are removed. In this case, of the protective film 240, a portion located on the pixel region 1 and a portion located on the resistance element 110 remain. After etching of the protective film 240, the insulating layers 203 and 204 covering the upper surfaces of the gate electrodes 121 and 122 are removed. The insulating layers 203 and 204 may be etched simultaneously with etching of the protective film 240, or etched independently. After etching the protective film 240 and the insulating layers 203 and 204, the mask pattern 420 is removed.

As shown in FIG. 5B, a metal film 250 is formed to cover the substrate 100 using a sputtering method, a CVD method, or the like. The metal film 250 is formed to contact the upper surfaces of the gate electrodes 121 and 122 and the regions 108 and 109, and contains a metal for silicidation the upper surfaces of the gate electrodes 121 and 122 and the regions 108 and 109. The metal film 250 contacts the protective film 240 on the pixel region 1 and the resistance element 110 which are not silicidation. The metal film 250 may have a stacked structure of a metal for silicidation and a metallic compound for suppressing oxidization of the metal. For example, the metal film 250 may be a stacked film of cobalt and titanium nitride for suppressing oxidization of cobalt.

After the formation of the metal film 250, the substrate 100 is heated to about 500° C., thereby causing the metal film 250 to react with the regions 108 and 109 and gate electrodes 121 and 122 all of which contact the metal film 250. This forms the silicide layers 132, 133, 134, and 135 in a monosilicide state. After that, the protective film 240 and the unreacted metal film 250 located on the side walls 215 are removed. If a layer of a metallic compound for suppressing oxidization of a metal is formed on the metal film 250, the layer of the metallic compound is also removed. After removing the unreacted metal film 250, the substrate 100 is heated to about 800° C. higher than that at the time of the first silicidation process, thereby changing the silicide layers 132, 133, 134, and 135 from the monosilicide state to a disilicide state. In this embodiment, heating to a different temperature is performed twice but the silicide layers 132, 133, 134, and 135 may be formed by performing heating once. Conditions for silicidation are appropriately selected in accordance with a kind of metal for forming silicide.

In the silicidation step, in the resistance element 110 and the pixel region 1 where the protective film 240 remains, the metal film 250 does not contact the substrate 100 and the gate electrodes, and thus no silicide layers are formed. The protective film 240 functions as a silicide block in this way. Since a silicide layer may cause noise in the pixel region 1, the pixel region 1 is covered with the protective film 240 at the time of silicidation. Especially, the region 101 serving as the photoelectric conversion unit 11, the region 103 serving as the node 14 for detecting charges, and the regions 104 and 105 serving as the source/drain regions of the amplification element 15 are not silicidation. Furthermore, since the resistance value may become too small in the resistance element 110, the resistance element 110 is protected by the protective film 240. After the formation of the silicide layers 132, 133, 134, and 135, the protective film 240 may be removed. To avoid unnecessary damage to the pixel region 1, the protective film 240 need not be removed. In this embodiment, the protective film 240 remains, as shown in FIG. 5C.

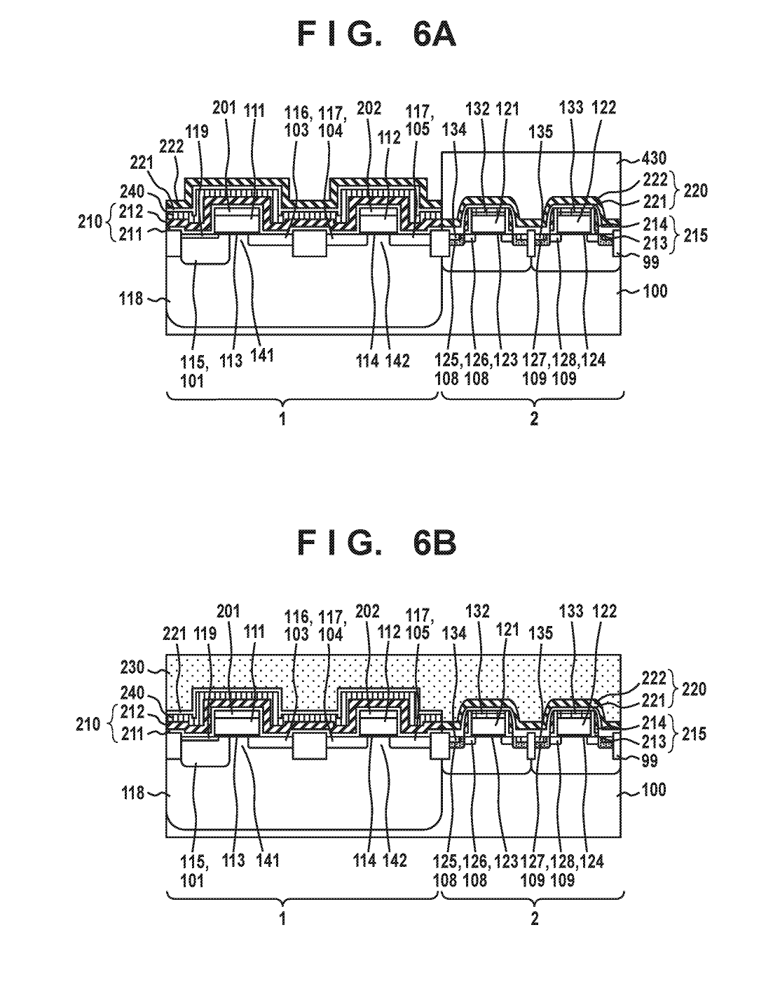

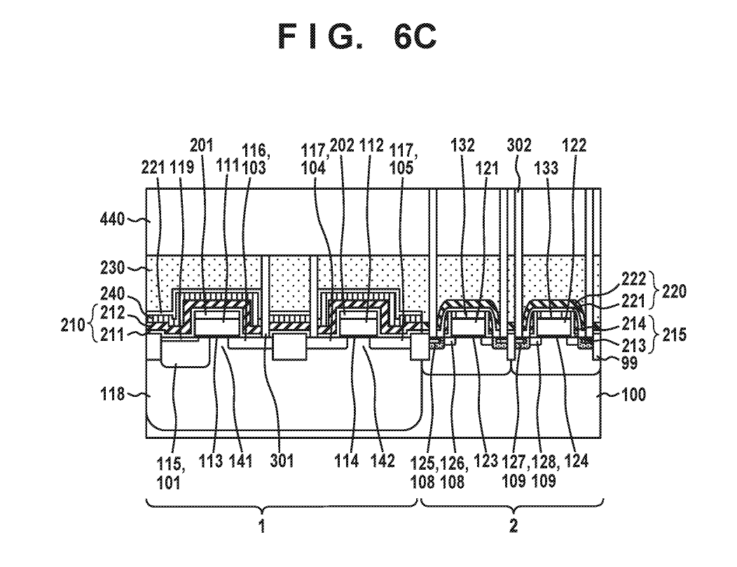

After the formation of the silicide layers 132, 133, 134, and 135, the insulating film 220 including the silicon oxide layer 221 and the silicon nitride layer 222 is formed, as shown in FIG. 6A. The insulating film 220 covers the upper surfaces of the gate electrodes 111, 112, 121, and 122, the side walls 215, the regions 103, 104, 105, 108, and 109 serving as the source/drain regions of the pixel transistors and the peripheral transistors, and the region 101.

The insulating film 220 is a stacked film of the silicon oxide layer 221 and the silicon nitride layer 222, and is formed so that the silicon oxide layer 221 and the silicon nitride layer 222 contact each other. The step of forming the insulating film 220 includes a step of forming the silicon oxide layer 221 and a step of forming the silicon nitride layer 222. The thickness of the silicon nitride layer 222 may be equal to or larger than that of the silicon oxide layer 221. The thickness of the silicon nitride layer 222 may be twice the thickness of the silicon oxide layer 221 or more. For example, the thickness of the silicon oxide layer 211 may fall within the range of 10 nm to 30 nm, and the thickness of the silicon nitride layer 212 may fall within the range of 20 nm to 100 nm.

The silicon oxide layer 211 is formed using a sub-atmospheric CVD (SA-CVD) method as a thermal CVD method in which the pressure (generated pressure) of the process gas containing a source gas such as TEOS falls within the range of 200 Pa to 600 Pa. In this case, the deposition temperature (substrate temperature) may fall within the range of 400° C. to 500° C. As described above, the silicon oxide layers 211 and 221 can be formed using the thermal CVD method.

The silicon nitride layer 222 is formed by the LPCVD method using, for example, the process gas containing NH₃ and HCD as source gases. In this case, the pressure (generated pressure) of the process gas may fall within the range of 20 Pa to 200 Pa, and the deposition temperature (substrate temperature) may fall within the range of 500° C. to 800° C.

The silicon nitride layer 222 can function as a chlorine supply film which stably supplies chlorine to the peripheral transistors. The thick silicon nitride layer 222 can contain chlorine abundantly, and the thin silicon oxide layer 221 can transmit chlorine appropriately. Furthermore, as described above, the silicon nitride layer 222 formed using the process gas containing HCD and NH₃ as source gases contains a large amount of hydrogen. It is thus possible to form the peripheral transistors with a superior noise characteristic. Since it is not necessary to consider an increase in k value in the peripheral transistors, the concentration of chlorine contained in the silicon nitride layer 222 may be equal to or higher than that of chlorine contained in the silicon nitride layer 212. For example, the concentration of chlorine contained in the silicon nitride layer 212 may be 3 atomic % or higher. Furthermore, the concentration of chlorine contained in the silicon nitride layer 212 may be 5 atomic % or higher. If the concentration of chlorine contained in the silicon nitride layer 212 is set to 5 atomic %, for example, the following deposition conditions can be adopted as the deposition conditions of the silicon nitride layer 212.

Deposition temperature: 500 to 700° C.
HCD: 60 to 150 sccm
NH₃: 800 to 1,600 sccm
Generated pressure: 10 to 200 Pa

The hexachlorodisilane/ammonia ratio (HCD/NH₃ ratio) of the process gas when forming the silicon nitride layer 212 may be equal to or lower than that when forming the silicon nitride layer 222. For example, the HCD/NH₃ ratio of the process gas when forming the silicon nitride layer 212 may fall within the range of 1/160 to 1/20, and the HCD/NH₃ ratio of the process gas when forming the silicon nitride layer 222 may fall within the range of 1/20 to 15/80. Furthermore, for example, the HCD/NH₃ ratio of the process gas when forming the silicon nitride layer 212 may fall within the range of 1/160 to 1/100, and the HCD/NH₃ ratio of the process gas when forming the silicon nitride layer 222 may fall within the range of 1/10 to 15/80.

After the formation of the insulating film 220, a mask pattern 430 is formed using a photoresist or the like to cover a portion, located in the peripheral circuit region 2, of the insulating film 220, as shown in FIG. 6A. A portion, arranged in the pixel region 1, of the silicon nitride layer 212 is etched and removed through the opening of the mask pattern 430. The removed portion of the silicon nitride layer 212 includes a portion, of the silicon nitride layer 212, located on the photoelectric conversion unit 11, the transfer element 12, the capacitive element 13, the amplification element 15, the reset element 16, and the selection element 17. In this case, the silicon oxide layer 221 can function as an etching stopper for removing, by etching, the silicon nitride layer 222 covering the pixel region 1. The silicon oxide layer 221 can also function as a protective layer which protects the pixel region 1 from damage by etching. By removing at least the silicon nitride layer 222 arranged on the photoelectric conversion unit 11 in the pixel region 1, it is possible to suppress a situation in which excessive chlorine is supplied to the photoelectric conversion unit 11 to increase the k value.

Next, the insulating film 230 is formed to cover the pixel region 1 and the peripheral circuit region 2. The insulating film 230 is a single-layer film of silicon oxide deposited by a plasma CVD method such as a high density plasma (HDP) CVD method. The insulating film 230 can be formed from an arbitrary material such as a BPSG film, a BSG film, or a PSG film. The insulating film 230 is not limited to a single-layer film, and may be a multilayer film.

As shown in FIG. 6B, the surface of the insulating film 230 is planarized. As a planarization method, a chemical mechanical polishing (CMP) method, a reflow method, an etch-back method, or the like is used. These methods may be used in combination. The thickness of the insulating film 230 before planarization can fall within, for example, the range of 200 nm to 1,700 nm. In this embodiment, since the portion, located on the pixel region 1, of the silicon nitride layer 222 is removed in the above-described step, the height difference of the underlayer of the insulating film 230 between the pixel region 1 and the peripheral circuit region 2 is small. Thus, the thickness of the insulating film 230 after planarization can be set to 1,000 nm or less. For example, the thickness of the insulating film 230 may fall within the range of 450 nm to 850 nm. By decreasing the thickness of the insulating film 230, it is possible to reduce the resistance of each contact plug and improve the sensitivity. The thickness of the insulating film 230 after planarization may be larger than those of the insulating films 210 and 220.

After the planarization of the insulating film 230, the electrically conductive members 311, 312, 313, and 314 for electrically connecting the pixel transistors and peripheral transistors to the wiring lines are formed. In the pixel region 1, openings are formed in the insulating film 230 by anisotropy dry etching through the openings of the mask pattern such as the photoresist covering the insulating film 230, and the contact holes 301 for providing the electrically conductive members 311 are formed. When forming the contact holes 301, the silicon nitride layer 212 of the insulating film 210 may be used as an etching stopper in the pixel region 1. The contact holes 301 are provided to extend through the insulating film 230, the silicon oxide layer 221, the protective film 240, the silicon nitride layer 212, and the silicon oxide layer 211. The contact holes 301 expose the source/drain regions of the capacitive element 13, amplification element 15, reset element 16, and selection element 17, and the reference contact region 102.

Simultaneously with the formation of the contact holes 301, the contact holes 303 which expose the gate electrodes of the capacitive element 13, amplification element 15, reset element 16, and selection element 17 are formed. The contact holes 303 for providing the electrically conductive members 313 extend through the insulating film 230, the silicon oxide layer 221, the protective film 240, the silicon nitride layer 212, and the silicon oxide layer 211. Furthermore, the contact holes for providing the electrically conductive members 313 extend through the insulating layers 201 and 202. To reduce the contact resistances of the contact plugs, an impurity may be implanted into the impurity regions and gate electrodes of the substrate 100 through the contact holes.

Before the formation of the contact holes 301, the silicon nitride layer 222 located on the pixel region 1 is removed, as described above. Therefore, there is no silicon nitride layer above the silicon nitride layer 212 used as an etching stopper. Consequently, when forming the contact holes 301, it is possible to suppress a situation in which the formation of the contact holes 301 is hindered in the silicon nitride layer other than the silicon nitride layer 212.

As shown in FIG. 6C, in the peripheral circuit region 2, openings are formed in the insulating film 230 by anisotropy dry etching using a mask pattern 440 which covers the insulating film 230 and has openings in the regions where the contact holes 302 and 304 are formed. This forms the contact holes 302 and 304 for providing the electrically conductive members 312 and 314. When forming the contact holes 302, the silicon nitride layer 222 of the insulating film 220 can be used as an etching stopper in the peripheral circuit region 2. The contact holes 302 and 304 are formed to extend through the insulating film 230, the silicon nitride layer 222, and the silicon oxide layer 221. The contact holes 302 expose the silicide layers 134 and 135 located in the regions 108 and 109 serving as the source/drain regions of the peripheral transistors. Simultaneously with the formation of the contact holes 302, the contact holes 304 which expose the silicide layers 132 and 133 of the gate electrodes 121 and 122 for providing the electrically conductive members 314 are formed.

After the formation of the contact holes 301, 302, 303, and 304, the contact holes 301, 302, 303, and 304 are filled with an electric conductor such as a metal, thereby forming the electrically conductive members 311, 312, 313, and 314 functioning as contact plugs. The contact holes 301, 302, 303, and 304 can be filled with the electrically conductive members at once.

A step of forming the contact holes 301 and 303 in the pixel region 1 and filling them with the electrically conductive members 311 and 313 and a step of forming the contact holes 302 and 304 in the peripheral circuit region 2 and filling them with the electrically conductive members 312 and 314 may be separated steps. By individually performing the step of forming contact plugs in the pixel region 1 and the peripheral circuit region 2, it is possible to suppress contamination of the impurity regions of the pixel region 1 through the contact holes 301 and 303 with a metal contained in the silicide layers 132, 133, 134, and 135. The steps of forming contact holes and filling them with the electrically conductive members in the pixel region 1 and the peripheral circuit region 2 may be performed in any order.

By performing the above steps, the structure shown in FIGS. 2A and 2B is obtained. After that, the wiring pattern, color filter, and microlens are formed to complete the solid-state image sensor 1000. A hydrogen annealing process for promoting hydrogen supply to the pixel transistors and peripheral transistors may be added in the state in which the peripheral transistors are covered with the insulating film 220. The hydrogen annealing process indicates a process of terminating the surface of the substrate 100 with hydrogen by heating the substrate 100 in a hydrogen atmosphere. The hydrogen annealing process may be performed after the formation of the electrically conductive members 311, 312, 313, and 314, and also after the formation of the wiring pattern.

Although the embodiments of the present invention have been explained above, the present invention is not limited to them, as a matter of course. The above-described embodiments can be changed or combined appropriately without departing from the spirit of the present invention. For example, in the above-described embodiments, among semiconductor devices, a solid-state image sensor has been exemplified to describe the present invention. The present invention, however, is not limited to the solid-state image sensor as long as the semiconductor device includes an insulated gate field-effect transistor, and is applicable to an arithmetic unit, storage device, control apparatus, signal processing apparatus, detection apparatus, display device, and the like.

As an application of the solid-state image sensor according to the above-described embodiment, a camera incorporating the solid-state image sensor 1000 will be exemplified. The camera conceptually includes not only an apparatus whose principal purpose is shooting but also an apparatus (for example, a personal computer or portable terminal) additionally provided with a shooting function. The camera includes the solid-state image sensor 1000 according to the present invention exemplified as the above embodiment, and a processing unit for processing information based on a signal output from the solid-state image sensor 1000. This processing unit can include a processor for processing digital data as image data. The processor can calculate a defocus amount based on signals from pixels having the focus detection function of the solid-state image sensor 1000, and perform processing for controlling focus adjustment of an imaging lens based on the defocus amount. An A/D converter for generating the image data can be provided in the solid-state image sensor 1000 or provided separately from the solid-state image sensor 1000.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2016-174963, filed Sep. 7, 2016 which is hereby incorporated by reference wherein in its entirety.

What is claimed is:

1. A solid-state image sensor comprising:
a pixel region including a photoelectric conversion unit formed in a substrate,
wherein a first silicon nitride layer is arranged to cover at least part of the photoelectric conversion unit, and
a concentration of chlorine contained in the first silicon nitride layer falls within a range of 1 atomic % to 3 atomic %.

2. The sensor according to claim 1, wherein
the pixel region further includes a first transistor, and
a distance between a surface of the substrate and a lower surface of a portion, covering the photoelectric conversion unit, of the first silicon nitride layer is shorter than a distance between the surface of the substrate and an upper surface of a gate electrode of the first transistor.

3. The sensor according to claim 1, wherein the concentration of chlorine contained in the first silicon nitride layer falls within a range of 2 atomic % to 2.5 atomic %.

4. The sensor according to claim 1, further comprising:
a peripheral circuit region including a second transistor formed in the substrate; and
a second silicon nitride layer that covers at least part of the second transistor and has a contact hole in which an electrically conductive member is arranged,
wherein the second silicon nitride layer contains chlorine.

5. The sensor according to claim 4, wherein a concentration of chlorine contained in the second silicon nitride layer is equal to or higher than the concentration of chlorine contained in the first silicon nitride layer.

6. The sensor according to claim 4, wherein
the second transistor includes a silicide layer on at least one of source/drain regions or a gate electrode, and
the second silicon nitride layer covers at least part of the silicide layer.

7. The sensor according to claim 4, wherein the second silicon nitride layer does not cover at least the photoelectric conversion unit of the pixel region.

8. The sensor according to claim 4, wherein
the second transistor includes, on a side surface of a gate electrode, a side wall including a third silicon nitride layer, and
a concentration of chlorine contained in the third silicon nitride layer falls within a range of 1 atomic % to 3 atomic %.

9. The sensor according to claim 8, wherein the concentration of chlorine contained in the first silicon nitride layer is equal to the concentration of chlorine contained in the third silicon nitride layer.

10. The sensor according to claim 1, wherein
the first silicon nitride layer contains silicon, nitride, hydrogen, and chlorine, and
a composition ratio of chlorine of the first silicon nitride layer is lower than a composition ratio of each of silicon, nitride, and hydrogen.

11. The sensor according to claim 1, wherein
in the pixel region, a first silicon oxide layer which contacts the first silicon nitride layer and is arranged between the substrate and the first silicon nitride layer is arranged, and
a thickness of the first silicon nitride layer is equal to or larger than a thickness of the first silicon oxide layer.

12. The sensor according to claim 1, wherein the first silicon nitride layer functions as an antireflection film.

13. A camera comprising:
a solid-state image sensor according to claim 1; and
a processing unit configured to process a signal output from the solid state image sensor.

14. A method of manufacturing a solid-state image sensor including a pixel region that includes a photoelectric conversion unit and a first transistor and a peripheral circuit region that includes a second transistor, the method comprising:
forming the pixel region and the peripheral circuit region in a substrate; and
forming a first silicon nitride layer to cover at least part of the photoelectric conversion unit,
wherein a concentration of chlorine contained in the first silicon nitride layer falls within a range of 1 atomic % to 3 atomic %.

15. The method according to claim 14, wherein in the forming the first silicon nitride layer, the first silicon nitride layer is formed using a first process gas containing hexachlorodisilane.

16. The method according to claim 15, wherein
in the forming the first silicon nitride layer, the second transistor is covered with the first silicon nitride layer, and
the method further comprises
etching the first silicon nitride layer to expose at least part of source/drain regions or a gate electrode of the second transistor, and
forming a second silicon nitride layer to cover at least part of the second transistor after the etching the first silicon nitride layer.

17. The method according to claim 16, wherein
the first process gas further contains ammonia,
in the forming the second silicon nitride layer, the second silicon nitride layer is formed using a second process gas containing hexachlorodisilane and ammonia, and
a hexachlorodisilane/ammonia ratio of the first process gas is not higher than a hexachlorodisilane/ammonia ratio of the second process gas.

18. The method according to claim 17, wherein a concentration of chlorine contained in the second silicon nitride layer is not lower than a concentration of chlorine contained in the first silicon nitride layer.

19. The method according to claim 17, wherein the hexachlorodisilane/ammonia ratio of the first process gas falls within a range of 1/160 to 1/20, and the hexachlorodisilane/ammonia ratio of the second process gas falls within a range of 1/20 to 15/80.
